(19) United States
(12) Patent Application Publication
(10) Pub. No.: US 2015/0062813 A1
(43) Pub. Date: Mar. 5, 2015

(54) COOLING DEVICE

(71) Applicant: Siemens Aktiengesellschaft, Muenchen (DE)

(72) Inventors: Martin Honsberg-Riedl, Teisendorf (DE); Jakob Löschke, Muenchen (DE); Gerhard Mitic, Muenchen (DE); Randolf Mock, Hohenbrunn (DE); Thomas Vontz, Muenchen (DE)

(21) Appl. No.: 14/389,853

(22) PCT Filed: Apr. 3, 2013
(86) PCT No.: PCT/EP2013/057022

§ 371 Date: Oct. 1, 2014

(30) Foreign Application Priority Data
Apr. 3, 2012 (DE) 10 2012 205 463.4
Aug. 31, 2012 (DE) 10 2012 215 484.1

(51) Int. Cl. H05K 7/20

(52) U.S. Cl. CPC H05K 7/20909; H05K 7/20145; H05K 7/20154
USPC 361/694

(57) ABSTRACT

A cooling device for cooling an electronic component, such as a power semiconductor, includes a cooling body which can be thermally coupled to the component, at least one sonotrode element for generating ultrasonic waves having a predetermined wavelength directed towards the cooling body, and a resonance tube that is associated with the sonotrode element and that is arranged between the sonotrode element and the cooling body, wherein a distance between the sonotrode element and the cooling body corresponds to an integral multiple of a quarter of a wavelength, such that a standing wave is formed between the at least one sonotrode element and the cooling body.

### REFERENCE TO RELATED APPLICATIONS

This is a U.S. national stage of application No. PCT/EP2013/057022 filed 3 Apr. 2013. Priority is claimed on German Application Nos. 102012205463.4 filed 3 Apr. 2012 and 102012215484.1 filed 31 Aug. 2012, the content of which are incorporated herein by reference in their entirety.

### BACKGROUND OF THE INVENTION

1. Field of the Invention

The invention relates to a cooling device for cooling an electronic component comprising a power semiconductor.

2. Description of the Related Art

For cooling thermally demanding electronic components, such as power semiconductors, passive-convective cooling with the aid of a cooling body is often not sufficient. In such cases, it is therefore necessary for an air flow that is directed toward the cooling body to be additionally actively generated.

Apart from the use of mechanical blowers that are both noisy and also prone to wear and tear, the use of ultrasonic transducers to this end is also known. Such transducers, such as piezoelectric sonotrodes, apart from the actual ultrasonic waves, also generate an air flow, referred to as ultrasonic wind, which is directed away from the transducer and which may be used for active cooling.

In comparison with mechanical blowers, however, only a comparatively low throughput of air is generated with ultrasonic transducers.

### SUMMARY OF THE INVENTION

It is thus an object of the present invention to provide an improved cooling device which enables improved heat conveyance away from electronic components and, in particular, generates an increased throughput of air.

This and other objects and advantages are achieved in accordance with the invention by providing a cooling device that is configured to cool an electronic component, in particular a power semiconductor. It displays at least one sonotrode element for generating ultrasonic waves of a predefined wavelength. The cooling device in accordance with the invention furthermore displays a tuned pipe that is assigned to the sonotrode element and that has a first opened end and a second opened end. In the cooling device in accordance with the invention, the sonotrode element is disposed so as to be closer to the first end than to the second end of the tuned pipe, or else the first end faces toward the sonotrode element. The distance from the sonotrode to the second end and/or from the first end to the second end substantially corresponds to an integral multiple of half of the wavelength. Alternatively or additionally to the respective distance, the flow path between the sonotrode and the second end and/or the flow path between the first end and the second end through the tuned pipe substantially corresponds to an integral multiple of half of the wavelength.

It should be understood that a distance or flow path that substantially corresponds to an integral multiple of half of the wavelength may slightly deviate, i.e., in particular by at most one eighth, preferably by at most one sixteenth, of the wavelength, from the integral multiple of half of the wavelength. Ideally, the deviations from the integral multiple of half of the wavelength are at most one thirtysecondth of the wavelength. Particularly and preferably, the distance or the flow path, in the context of the production tolerance, exactly corresponds to an integral multiple of half of the wavelength.

On account of this geometric arrangement, an antinode of the ultrasonic waves that are excited in a resonant manner by the sonotrode element is configured at the second end of the tuned pipe. A standing wave is thus generated between the sonotrode element and the second end of the tuned pipe, or between the first end and the second end of the tuned pipe. In the case of the cooling body in accordance with the invention, the oscillation conditions, as described above, thus correspond to those of an open organ pipe.

On account of the ultrasonic field that oscillates in the tuned pipe, in comparison with arrangements that are free of a tuned pipe, a significantly increased flow speed of the flowing air is achieved at the second end of the tuned pipe. Consequently, heat transfer of a cooling body that is disposed so as to be close to the second end to the flowing air is significantly improved.

The first end of the tuned pipe is particularly expediently spaced apart from the sonotrode by a multiple of half of the wavelength, where the first and the second end of the tuned pipe moreover are spaced apart from one another by a multiple of half of the wavelength, or else the flow path between the first and the second end is a multiple of half of the wavelength. In this manner, resonances that are configured between the first and the second end, and between the sonotrode element and the second end, may be advantageously superimposed on one another and reinforced.

In the cooling device in accordance with the invention, the sonotrode element is expediently disposed outside the tuned pipe and/or at the face side in relation thereto. In this manner, the sonotrode element is able to excite resonances in the tuned pipe in a particularly efficient manner.

The cooling device in accordance with the invention furthermore advantageously comprises a cooling body that is couplable to the component and that is disposed so as to be close to the second end of the tuned pipe, in particular so as to be at the face side in relation thereto and/or so as to be outside of the tuned pipe. The air that exits from the tuned pipe and, in comparison to the prior art, which is significantly increased in its flow rate, may in this manner suitably expose the cooling body to heat-evacuating air.

In the case of the cooling device in accordance with the invention, an air gap is preferably provided between the second end of the tuned pipe and the cooling body. On account thereof, an outflow of the air flow supplied by the ultrasonic wind is enabled.

In the case of the cooling device in accordance with the invention, the distance between the sonotrode element and the second end of the tuned pipe and/or between the first and the second end of the tuned pipe and/or the flow path through the tuned pipe between the sonotrode and the second end of the tuned pipe and/or between the first and second end of the tuned pipe ideally corresponds to half and/or one and/or one and a half and/or two and/or two and a half and/or three wavelength(s). In practice, resonances can be efficiently excited in this manner.

In the case of the cooling device in accordance with the invention, the diameter of the tuned pipe expediently substantially corresponds to the wavelength. In this case, resonances in the tuned pipe can be particularly easily excited.

It should be understood that a diameter of the tuned pipe that substantially corresponds to the wavelength may also slightly deviate from the wavelength, i.e., in particular by at most one eighth of the wavelength, preferably by at most one sixteenth of the wavelength. Ideally, the deviations from the integral multiple of half of the wavelength are at most one thirtysecondth of the wavelength.

In the case of the cooling device in accordance with the invention, the first end of the tuned pipe particularly preferably displays a cutting edge. By means of the cutting edge, the resonant effect of the tuned-pipe flow is reinforced at the inlet of the air flow, as in the case of an organ pipe. On account of the geometry of the cutting edge and/or of the first end of the tuned pipe and/or of the sonotrode element, the air flow is ideally channeled such that it exactly impinges the cutting edge, in particular via the at least one suitably provided flow-conducting means.

In one preferred embodiment of the invention, a wall of the tuned pipe, at the first end on its inside, is inclined in relation to the longitudinal extent of the tuned pipe, suitably such that the wall, at the first end or toward the first end, tapers in a pointed manner.

Alternatively or additionally, the wall of the first end of the tuned pipe, on its outer side, is inclined in relation to the longitudinal extent of the tuned pipe, suitably such that the wall, at the first end or toward the first end, tapers in a pointed manner.

In one particularly preferred embodiment of the invention, in the case of the cooling device a flow-conducting structure, via which flowing air is conductible so as to impinge on the cutting edge, is additionally provided.

The flow-conducting structure is expediently disposed and configured such that the flow-conducting structure displays at least one flow duct, where the cross-sectional face of the flow duct is reduced close to the cutting edge. The flow duct is expediently disposed so as to be axially aligned with the tuned pipe. The flow duct is suitably disposed on an end that is remote from the cutting edge, close to the sonotrode element.

The flow-conducting structure preferably displays at least one flow-conducting pipe and at least one flow-limiting device that interacts with the flow-conducting pipe so as to form at least one flow duct. The conducting pipe is preferably disposed so as to be axially aligned with the tuned pipe. In one expedient embodiment of the invention, the flow-limiting device is a funnel, cone, or truncated cone, which is disposed so as to be axially aligned with the tuned pipe and lies within the conducting pipe, and which toward the tuned pipe widens along the longitudinal axis of the flow-conducting pipe and is preferably configured in a solid manner. In this manner, an outlet opening of the flow-conducting pipe in the radial direction may overlap with the cutting edge. In this manner, a particularly good exposure of the cutting edge to the flow is achieved.

The throughput of air generated by the ultrasonic transducers, and thus the cooling power, may be improved by suitable measures as have been described above.

Even having a reinforced throughput of air of the solution in accordance with the invention, as described above, in the case of active cooling using ultrasonic transducers, on account of the configuration of a static air barrier layer on the surface of the cooling body, the heat transfer on the moving air flow of the ultrasonic wind is, however, occasionally limited.

By means of the cooling device in accordance with the invention, which is described in the following, at least to the extent that they do not correspond to the features described above, may be alternatively or additionally available to the features of the cooling device in accordance with the invention as described above, an in comparison further improved thermal evacuation of electronic components is enabled.

Such a cooling device in accordance with the invention for cooling an electronic component, i.e., a power semiconductor, comprises a cooling body that is thermally coupled to the component, at least one sonotrode element for generating ultrasonic waves of a predefined wavelength that are directed toward the cooling body, and a tuned pipe that is assigned to the sonotrode element and that is disposed between the sonotrode element and the cooling body. Here, it is provided in accordance with the invention that a distance between the sonotrode element and the cooling body corresponds to an integral multiple of a quarter of the wavelength.

On account of this geometric arrangement, wave nodes are configured on the surface of the cooling body. As a result, a static wave is thus generated between the sonotrode element and the cooling body. In contrast to the arrangement described above, the oscillation conditions thus no longer correspond to those of an open organ pipe but rather a covered organ pipe.

On account of the oscillating ultrasonic field, the thickness of the stagnant barrier layer on the surface of the cooling body is substantially reduced, such that the thermal transfer to the flowing air is significantly improved. Turbulences that significantly facilitate the thermal exchange between the cooling body and the air may be formed, in particular, in the region of the barrier layer, such that the cooling efficiency of such a device is particularly good.

In a further embodiment of the invention, an air gap is provided between a cooling-body end of the tuned pipe and the cooling body. On account thereof an outflow of the air flow that is supplied by the ultrasonic wind is enabled. The gap width here may be suitably selected; it is possible, for example, for a gap width of quarter of the ultrasonic wavelength to be chosen, such that an antinode is present at the opening of the tuned pipe.

It is furthermore expedient to provide at least one flow-conducting element in a surface region of the cooling body which faces toward the cooling-body side end of the tuned pipe. On account thereof, the outflow of the ultrasonic wind may be controlled in a targeted manner. This is particularly advantageous when a plurality of sonotrode elements and assigned tuned pipes are to be used. By way of a suitable configuration of the flow-conducting elements, a negative influence of the individual air flows of the sonotrode elements on one another may be prevented.

In one possible embodiment, the flow-conducting element is configured for diverting by 180° an air flow that enters in the direction of a surface normal of the surface of the cooling body. The ultrasonic wind here is thus dissipated in a counter-parallel manner to its direction of entry. This is particularly expedient in combination with an air dissipation duct that runs parallel to the tuned pipe and that guides the air flow away from the surface of the cooling body in a perpendicular manner.

However, an alternative embodiment in which the flow-conducting element is configured for diverting by 90° an airflow that enters in the direction of a surface normal of the surface of the cooling body is particularly space-saving.

In this case, the entering ultrasonic wind is thus dissipated toward the periphery of the cooling body. It is particularly expedient here for the flow-conducting element to extend up to a peripheral region of the surface of the cooling body.

The flow-conducting element, in the surface, of the cooling body, here may configure a sunken duct the width of which substantially corresponds to the diameter of the tuned pipe. A helical geometry of the flow-conducting element, which extends to the periphery of the cooling body, is also possible. Depending on the arrangement of the individual sonotrode elements, other geometries may also be expedient.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention and its embodiments are described in more detail in the following by means of the drawing, in which:

FIG. 1 shows a schematic sectional illustration of a cooling device in accordance with the invention;

FIG. 2 shows a schematic sectional illustration of a further exemplary embodiment of a cooling device in accordance with the invention, having a tuned pipe with a cutting edge;

FIG. 3 shows a schematic sectional illustration of a further exemplary embodiment of a cooling device in accordance with the invention having a tuned pipe with a cutting edge;

FIG. 4 shows a schematic sectional illustration of a further exemplary embodiment of a cooling device in accordance with the invention having a tuned pipe with a cutting edge;

FIG. 5 shows a schematic sectional illustration of a further exemplary embodiment of a cooling device in accordance with the invention having a tuned pipe with a cutting edge and a flow-conducting structure;

FIG. 6 shows a schematic sectional illustration of the exemplary embodiment of the cooling device in accordance with the invention, of FIG. 1;

FIG. 7 shows a schematic sectional illustration of a further exemplary embodiment of a cooling device in accordance with the invention;

FIG. 8 shows a schematic sectional illustration of the cooling device of FIG. 6, with a depiction of the thermal insulation layer on the surface of the cooling device;

FIG. 9 shows a schematic sectional illustration of the exemplary embodiment of the cooling device in accordance with the invention of FIG. 7, with a depiction of the thermal insulation layer on the surface of the cooling body;

FIG. 10 shows a perspective view of an exemplary embodiment of a cooling device in accordance with the invention having a plurality of sonotrodes;

FIG. 11 shows a schematic sectional illustration of an exemplary embodiment of a cooling device in accordance with the invention having a flow duct for dissipating the heated air, which runs parallel to the tuned pipe;

FIG. 12 shows a perspective view of a cooling body having flow-conducting elements, for use in an exemplary embodiment of a cooling device in accordance with the invention; and

FIG. 13 shows a perspective view of an alternative cooling body having flow-conducting elements for use in an exemplary embodiment of a cooling device in accordance with the invention.

### DETAILED DESCRIPTION OF THE PREFERRED EMBODIMENTS

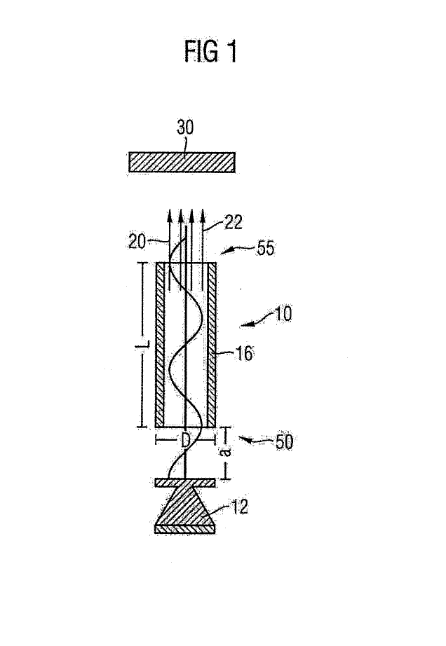

The cooling device 10 illustrated in FIG. 1 serves for actively cooling a semiconductor component (not explicitly illustrated in FIG. 1). The cooling device 10 comprises a piezoelectric sonotrode 12 and a cooling body 30 that is thermally coupled to the semiconductor. Between the sonotrode 12 and the cooling body 30 a circular-cylindrical tuned pipe 16 having a first 50 and a second opened end 55 is disposed such that the first opened end 50 points toward the sonotrode 12 and the second opened end 55 of the tuned pipe 16 points toward the cooling body 30.

In the illustration shown, the sonotrode 12 emits ultrasonic waves having a predefined wavelength into the first end 50 of the tuned pipe 16. Here, the length L of the tuned pipe 16 corresponds to substantially one and a half wavelengths. In other exemplary embodiments that are not specifically illustrated, the length L of the tuned pipe 16 is another integral multiple of half of the wavelength. The first end 50 of the tuned pipe 16 is spaced apart from the sonotrode 12 by half of a wavelength, the distance a. On account of this arrangement and configuration, standing ultrasonic waves are configured both between the first end 50 and the second end 55 of the tuned pipe 16 and also between the sonotrode 12 and the second end 55 of the tuned pipe 16. Here, the diameter D of the tuned pipe 16 corresponds to one wavelength. On account of the diameter, the configuration of standing waves is thereby significantly supported.

These standing waves configure in each case an antinode 20 on the second end 55. On account thereof, apart from the ultrasonic oscillation per se, the air flow generated by the sonotrode 12, i.e., ultrasonic wind, in the direction of the arrows 22 is reinforced.

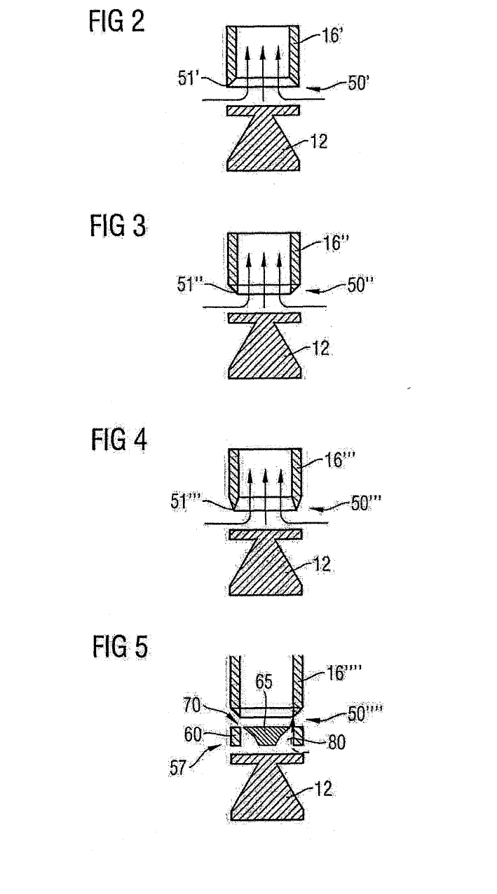

As is illustrated in the exemplary embodiments illustrated in FIGS. 2 to 5, the excitement of the standing waves is further improved in that a cutting edge 51′, 51″, 51′″ that allows an improved excitement of the air flowing into the pipe is provided on the first end 50′, 50″, 50′″, 50″″.

As shown for example in FIG. 2, the cutting edge 51′ here is configured such that the wall of the tuned pipe 16′, at the first end 50′ of the tuned pipe 16′, on the inside, is inclined in relation to the direction of the longitudinal extent L of the tuned pipe 16′, specifically such that the wall, at the first end 50′, tapers in a pointed manner toward the sonotrode 12.

Alternatively, the wall of the tuned pipe 16′, at the first end 50″ of the tuned pipe 16″, on the outer side, may be inclined in relation to the direction of the longitudinal extent L of the tuned pipe 16″ such that the wall tapers in a pointed manner at the first end 50″ and thus forms a cutting edge 51″ (FIG. 3).

As illustrated in FIG. 4, the wall of the tuned pipe 16′″, at the first end 50′″ of the tuned pipe, both on the inner side and also on the outer side, may also furthermore be inclined so as to taper in a pointed manner in relation to the direction of the longitudinal extent L of the tuned pipe 16′″ and thus form a cutting edge 51′″.

In the arrangement illustrated in FIG. 5 (which otherwise corresponds to the arrangement illustrated in FIG. 3) a flow-conducting structure 57, by which flowing air can be conducted so as to impinge on a cutting edge 51″, is provided in the case of the cooling device. In principle, cutting edges as illustrated in FIG. 2 or 4 may also be present in further exemplary embodiments which are not specifically illustrated.

The flow-conducting structure 57 displays a flow-conducting pipe 60 that is disposed so as to be axially aligned in relation to the tuned pipe 16″″ and so as to be between the sonotrode 12 and the tuned pipe 16″″. The flow-conducting structure 57 furthermore displays a solid funnel 65 that is disposed within the flow-conducting pipe 60 and which widens along the flow-conducting pipe 60 toward the tuned pipe 16″″. A flow duct 80 is thus configured between the funnel 65 and the flow-conducting pipe 60. Close to the tuned pipe 16″″ this flow duct 80 displays an outlet opening 70 having a reduced cross-sectional face, from which air flowing through the flow-conducting structure 57 may flow out. This outlet opening 70 of the flow-conducting structure 57 in the radial direction overlaps with the cutting edge 51″.

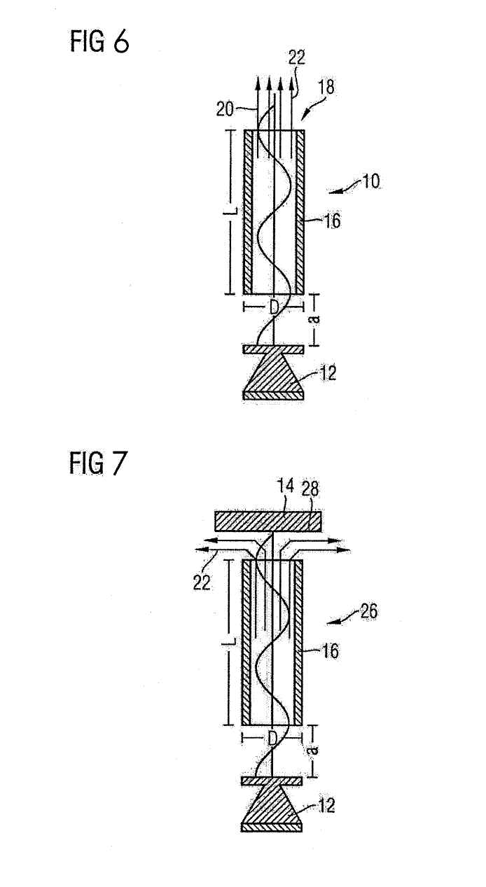

Cooling devices. 10 in accordance with the invention, as have been described above and illustrated in FIGS. 6 and 8 can be employed for actively cooling semiconductor components. As already described above, such cooling devices comprise a piezoelectric sonotrode 12 and a cooling body (henceforth, and in the figures described in the following, and in the further description identified by the reference sign 14 instead of the reference sign 30) which is thermally coupled to the semiconductor, between which a tuned pipe 16 is disposed.

At the cooling-body end (henceforth, and in the figures described in the following, and in the further description identified by the reference sign 18 instead of the reference sign 55) of the tuned pipe, an antinode 20 of the ultrasonic oscillation generated by the sonotrode 12 is configured here. On account thereof, apart from the ultrasonic oscillation per se, the air flow generated by the sonotrode 12, i.e., ultrasonic wind, in the direction of the arrows 22 is reinforced.

As shown in FIG. 8, the thermal evacuation from the cooling body 14 is occasionally hampered by a barrier layer 24 of stagnant air.

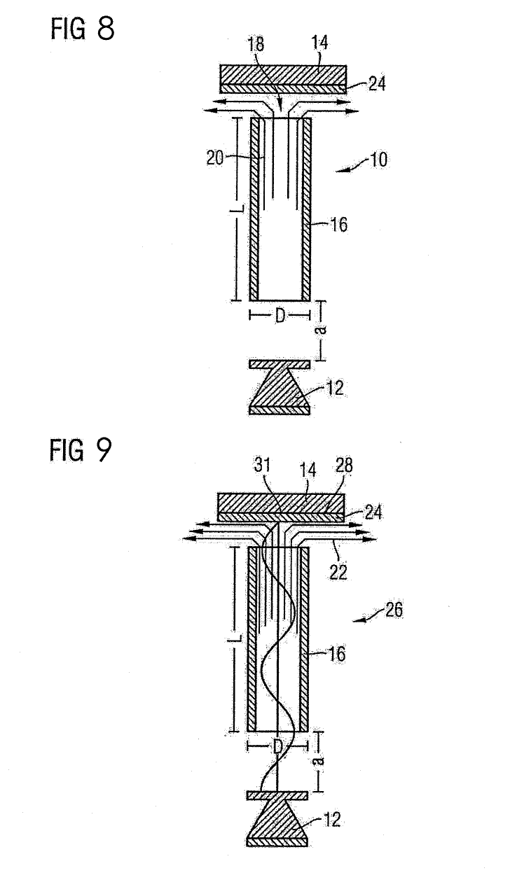

In order to attenuate the configuration of the barrier layer 24, in the further exemplary embodiment of a cooling device 26 in accordance with the invention, shown in FIGS. 7 and 9, the distance between the sonotrode 12 and the surface 28 of the cooling body 14 is selected such that it is an integral multiple of quarter of the wavelength of the ultrasound generated by the sonotrode 12.

On account thereof an oscillation node 31 is created on the surface 28 of the cooling body 14. A standing wave is thus configured between the sonotrode 12 and the surface 28. The standing wave reduces the extent of the barrier layer 24, such that the barrier layer 24 displays a significantly smaller thickness than in the cooling devices 10 which have been described above. On account of the standing wave, in particular, turbulences in the region of the surface 28, which counteract the formation of a barrier layer and improve the thermal evacuation from the cooling body 14, are generated.

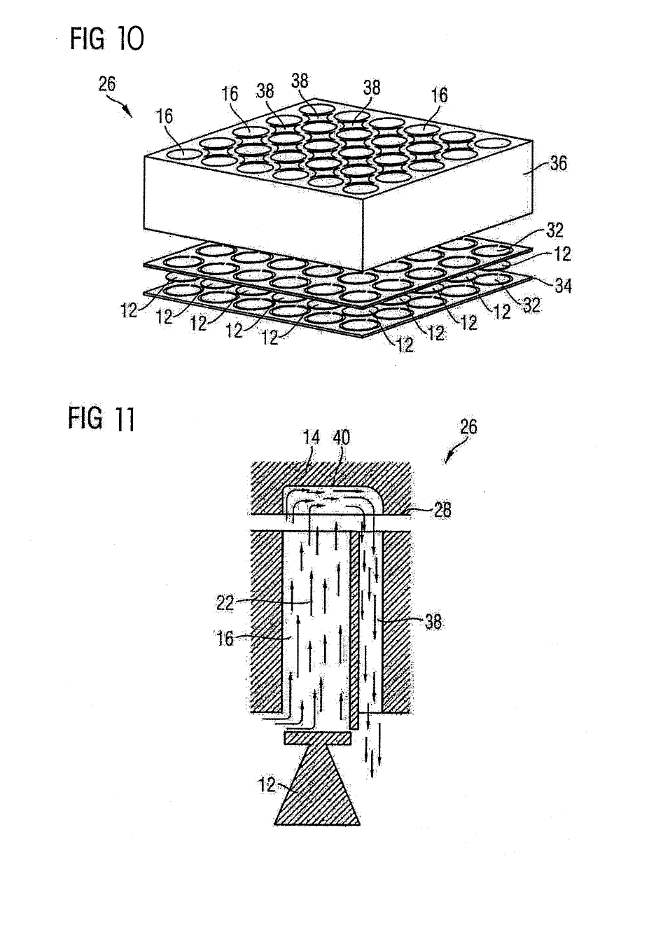

FIG. 10 shows a perspective view of a cooling device 26 without the cooling body 14. The cooling device 26 comprises a plurality of piezoelectric sonotrodes 12 that are enclosed between electrodes 32, 34. The tuned pipes 16 assigned to the sonotrodes 12 are collectively received in a block 36 and, for the sake of clarity, not all identified.

Together with the tuned pipes 16, further flow ducts 38 that are likewise not all identified are introduced into the block 36. The flow ducts 38, in interaction with the flow-conducting elements 40 on the surface 28 of the cooling body 14, serve for dissipating heated air from the surface 28.

As depicted in FIG. 11, the entering ultrasonic wind, after exiting from the tuned pipe 16 and when impinging the flow-conducting element 40, is deflected by 180° and guided into the flow duct 38, such that the heated air is evacuated from the cooling body 14. On account thereof, it is in particular avoided that the air flows, which are generated by adjacent sonotrodes 12, influence one another in a negative manner. Uniformly good heat dissipation is thus generated across the entire surface of the cooling body 14.

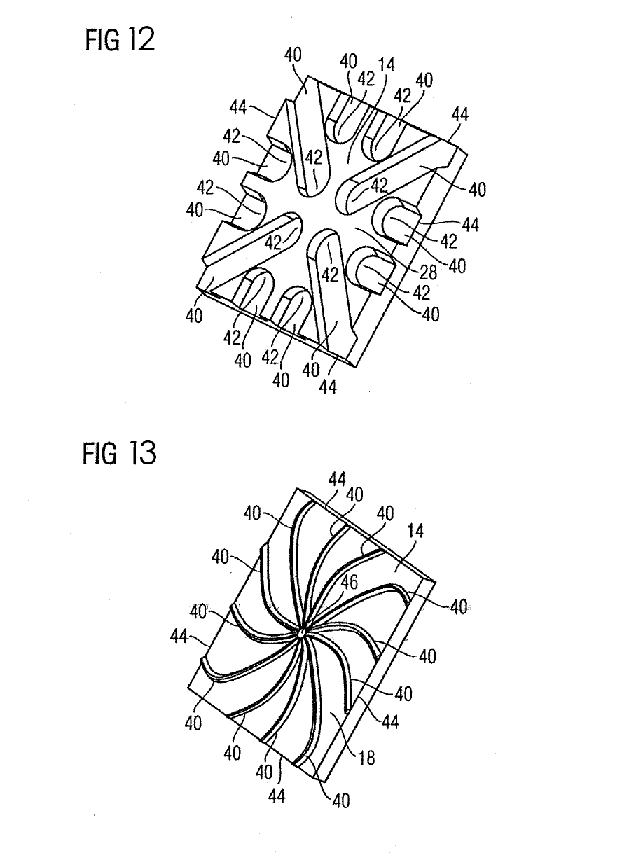

FIGS. 12 and 13 show alternative embodiments of the flow-conducting elements 40 on the surface 28 of the cooling body 14. In the embodiment of FIG. 12, the flow conducting elements 40 are configured as sunken ducts that extend from the mouth regions 42 of the tuned pipes (not shown) toward the periphery 44 of the cooling body 14. The ducts here display a width that corresponds to about the diameter of the tuned pipes 16.

In the embodiment depicted in FIG. 13, the flow-conducting elements 40 are configured as raised webs on the surface 28 of the cooling body 14, which extend from a center 46 of the surface 28 along helical paths to the periphery 44 of the cooling body.

It should be understood that the disclosed embodiments of invention are not limited to the geometries of the flow-conducting elements 40 shown in FIGS. 11 to 13. Depending on the configuration of the cooling body 14 and the amount of air and/or heat to be evacuated, other embodiments may also be expedient.

Thus, while there have been shown, described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1-16. (canceled)

17. A cooling device for cooling an electronic component, comprising:
at least one sonotrode element for generating ultrasonic waves of a predefined wavelength; and
a tuned pipe assigned to the sonotrode element and including a first opened end and a second opened end;
wherein one of (i) the sonotrode element is disposed so as to be closer to the first end than to the second end and (ii) the first end faces toward the sonotrode element; and
wherein one of (i) a distance from the sonotrode element to the second end and (ii) a distance from the first end to the second end substantially corresponds to an integral multiple of half of a wavelength.

18. A cooling device for cooling an electronic component, comprising:
at least one sonotrode element for generating ultrasonic waves of a predefined wavelength; and
a tuned pipe is assigned to the sonotrode element and including a first opened end and a second opened end;
wherein one of (i) the sonotrode element is disposed so as to be closer to the first end than to the second end and (ii) the first end faces toward the sonotrode element; and
wherein at least one of (i) a flow path between the sonotrode and the second end and (ii) a flow path from the first end to the second end through the tuned pipe substantially corresponds to an integral multiple of half of the wavelength.

19. The cooling device as claimed in claim 17, further comprising:
a cooling body which is couplable to the electronic component and disposed so as to be proximate the second end of the tuned pipe.

20. The cooling device as claimed in claim 19, wherein the is cooling body disposed at least one of (i) at a the face side in relation to the second end of the tuned pipe and (ii) outside the tuned pipe.

21. The cooling device as claimed in claim 19, wherein an air gap is provided between the second end of the tuned pipe and the cooling body.

22. The cooling device as claimed in claim 17, wherein the first end of the tuned pipe includes a cutting edge.

23. The cooling device as claimed in claim 17, further comprising:
a flow-conducting structure for by means of which flowing and conducting air so as to impinge on the cutting edge.

24. The cooling device as claimed in claim 17, wherein the flow-conducting structure includes at least one flow duct which tapers to a position proximate the cutting edge; and
wherein a cross-sectional face of the flow duct is reduced at the position proximate the cutting edge.

25. A cooling device for cooling an electronic component, comprising:
a cooling body which is thermally couplable to the electronic component;
at least one sonotrode element for generating ultrasonic waves of a predefined wavelength which are directed toward the cooling body; and
a tuned pipe assigned to the sonotrode element and disposed between the sonotrode element and the cooling body;
wherein a distance between the sonotrode element and the cooling body corresponds to an integral multiple of quarter of a wavelength.

26. The cooling device as claimed in claim 25, wherein an air gap is provided between a cooling-body side end of the tuned pipe and the cooling body.

27. The cooling device as claimed in claim 25, further comprising:
at least one flow-conducting element provided in a surface region of the cooling body which faces toward a cooling-body side end of the tuned pipe.

28. The cooling device as claimed in claim 26, further comprising:
at least one flow-conducting element provided in a surface region of the cooling body which faces toward a cooling-body side end of the tuned pipe.

29. The cooling device as claimed in claim 27, wherein the flow-conducting element is configured to divert an air flow which enters in a direction of a surface normal to the surface region of the cooling body by 180°.

30. The cooling device as claimed in claim 29, further comprising:
an air outlet duct which extends parallel to the tuned pipe.

31. The cooling device as claimed in claim 29, wherein the flow-conducting element is configured to divert an air flow which enters in a direction of a surface normal to the surface region of the cooling body by 90°.

32. The cooling device as claimed in claim 31, wherein the flow-conducting element extends to a peripheral region of the surface region of the cooling body.

33. The cooling device as claimed in claim 31, wherein the flow-conducting element, within the surface region of the cooling body, is configured as a sunken duct having a width which substantially corresponds to a diameter of the tuned pipe.

34. The cooling device as claimed in claim 32, wherein the flow-conducting element, within the surface of the cooling body, is configured as a sunken duct having a width which substantially corresponds to a diameter of the tuned pipe.

35. The cooling device as claimed in claim 31, wherein the flow-conducting element describes a helical path curve.

36. The cooling device as claimed in claim 32, wherein the flow-conducting element describes a helical path curve.

37. The cooling device as claimed in claim 17, wherein in the cooling device comprises a power semiconductor.

38. The cooling device as claimed in claim 18, wherein in the cooling device comprises a power semiconductor.

39. The cooling device as claimed in claim 25, wherein in the cooling device comprises a power semiconductor.
